(19) United States
(12) Patent Application Publication
(10) Pub. No.: US 2009/0163007 A1
(43) Pub. Date: Jun. 25, 2009

(54) METHOD FOR MANUFACTURING SEMICONDUCTOR DEVICE

(75) Inventor: Yasuhiko UEDA, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/338,653

(22) Filed: Dec. 18, 2008

(30) Foreign Application Priority Data
Dec. 21, 2007 (JP) 2007-329871

(51) Int. Cl. H01L 21/28

(52) U.S. Cl. 438/585; 257/E21.19

(57) ABSTRACT

A semiconductor device is manufactured suppressing generation of “vacancy-oxygen complex defects”. A general etching treatment is done using a general plasma gas including HBr, Cl₂ and O₂ till a time point when at least a part of a gate oxide film is exposed during a dry-etching step. After this time point a surface treatment is done using a plasma gas including a halogen atom having an atomic weight not less than Cl and a rare gas atom having an atomic weight not less than Ar in the same chamber. The generation of the defects which cannot be restored by heat treatment can be suppressed.

### REFERENCE TO RELATED APPLICATION

This application is based upon and claims the benefit of the priority of Japanese patent application No. 2007-329871, filed on Dec. 21, 2007, the disclosure of which is incorporated herein in its entirety by reference thereto.

### FIELD OF THE INVENTION

This invention relates to a method for manufacturing semiconductor device, and particularly relates to a dry etching treatment during formation of a gate structure.

### BACKGROUND

As regards semiconductor memories used for such as mobile products it is one of the most important requirements to reduce power consumption of the semiconductor memories. For this purpose minimizing leak current in the semiconductor is necessary. A leak current, especially flowing into a silicon substrate from a source drain diffusion layer which sandwiches a gate, is not negligible.

A gate oxide film and a silicon substrate beneath the film are irradiated by a high energy ion beam just after exposure of the gate oxide film to the surface due to removal of a conductive layer during a plasma etching step to form a gate structure. Then the gate oxide film and the silicon substrate are physically damaged.

Technical methods to restore physical damage occurred in a gate oxide film are disclosed in Patent Document 1 and Patent Document 2. Both methods have a common feature to repair defects by heat treatment in a predetermined gas environment.

On the other hand, defects in a silicon substrate may also be restored by the heat treatment. If the defects are restored by the heat treatment, no problem of the transistor will be observed in performance. However, an overheat treatment of the transistor may cause a problem that an ideal implantation profile cannot be obtained because a re-distribution of the implanted ions will occur due to the heat treatment. In addition, certain kind of defect may remain unrepaired after a heat treatment. Although the cause of the defect unrestored by the heat treatment is not clarified yet, Non-Patent document 1 proposes a “vacancy-oxygen complex defect” as a hypothesis of the generation process of the defect (Non-Patent document 1). Such defects may cause a formation of redundant energy level (recombination center) and a leak current produced by a flow of carriers via the energy level.

### [Patent Document 1]

JP Patent Kokai Publication No. JP-P2006-203228A

### [Patent Document 2]

JP Patent Kokai Publication No. JP-P2001-094105A

### [Non-Patent Document 1]

“Single silicon vacancy-oxygen complex defect and variable retention time phenomenon in dynamic random access memories” Takahide Umeda et. al., Applied Physics Letters, 88, 253504, 2006.

### SUMMARY OF THE DISCLOSURE

The entire disclosures of Patent Documents 1 to 2 and Non-Patent Document 1 are incorporated herein by reference thereto. The following analyses are given by the present invention.

It is an object of the present invention to provide an appropriate treatment method for processing the defect that cannot be restored by a heat treatment such as the “vacancy-oxygen complex defect” and to provide a method for manufacturing a semiconductor device based on the treatment method.

A combination gas of hydrogen bromide (HBr) gas and oxygen (O₂) gas is mainly used for a gate etching usually. However, a silicon substrate tends to be damaged when this gas composition is used, especially under the condition that a gate oxide film is exposed.

The reason why the silicon substrate is damaged and the “vacancy-oxygen complex defect” is formed although the substrate is covered by the gate oxide film is considered that high energy small ions of relatively small atomic weight such as hydrogen or oxygen are implanted into the substrate. The damage of the silicon substrate will be impermissibly large when these small ions are mainly used for the reaction in the etching step.

According to the above contemplation it is preferable to use rare gases of relatively large atomic weights as an energy source for the reaction step. The inventors have found a method to treat the surface of the gate oxide film using a plasma gas including a halogen atom having an atomic weight not less than chlorine (Cl) and a rare gas atom having an atomic weight not less than argon (Ar). A bromine (Br) atom, for example, is effective as a halogen atom. According to this example, the same etching effect as that of the conventional will be obtained with reduced consumption of plasma gas including atoms of smaller atomic weights such as hydrogen. Using rare gas such as helium (He) or neon (Ne) of relatively small atomic weight instead of Ar shows less effect.

According to an aspect of the present invention, there is provided a first manufacturing method of a semiconductor device. The method comprises: forming a gate oxide film on a semiconductor substrate, forming a conductive layer on the gate oxide film, and dry-etching the conductive layer to form a gate. The method further comprises treating a surface of the gate oxide film using a plasma gas including a halogen atom having an atomic weight not less than chlorine (Cl) and a rare gas atom having an atomic weight not less than argon (Ar).

According to another aspect of the present invention, there is provided a second manufacturing method of a semiconductor device. The surface treatment of the method starts just after exposure of at least a part of the gate oxide film.

According to another aspect of the present invention, there is provided a third manufacturing method of a semiconductor device. The surface treatment of the method starts after completion of the dry-etching.

According to another aspect of the present invention, there is provided a fourth manufacturing method of a semiconductor device. The dry-etching of the method is performed using a plasma gas comprising HBr, Cl₂ and O₂.

According to another aspect of the present invention, there is provided a fifth manufacturing method of a semiconductor device. The halogen atom of the method may be (or comprise) bromine (Br).

According to another aspect of the present invention, there is provided a sixth manufacturing method of a semiconductor device. The rare gas atom of the method may be (or comprise) argon (Ar).

According to another aspect of the present invention, there is provided a seventh manufacturing method of a semiconductor device. The conductive layer of the method may include at least one element of a group of Si, W, Ti, Co, Al, Ta and Ni.

The meritorious effects of the present invention are summarized as follows.

According to the present invention, generation of defects which cannot be restored by a heat treatment can be suppressed only by addition of plasma treatment for a short time, e.g., several tens of seconds, in the chamber just after exposure of the gate oxide film subsequently in the same chamber during the gate etching step.

### BRIEF DESCRIPTION OF THE DRAWINGS

FIG. 1 shows a relation of lifetime to each treatment condition level according to the present invention.

FIG. 2 shows an example of a process for fabricating a silicon substrate having a gate oxide film and a conductive layer used for the determination of the lifetime.

### PREFERRED MODES OF THE INVENTION

Some exemplary embodiments according to the present invention of a method for manufacturing a semiconductor device are described in detail.

An exemplary method for manufacturing a semiconductor device according to the present invention comprises: forming a gate oxide film on a semiconductor substrate, forming a conductive layer of poly-silicon on the gate oxide film, and dry-etching the conductive layer to form a gate structure.

The dry-etching step comprises a general etching step and a surface treatment step. The general etching step is carried out before the gate oxide film is exposed and after a time point at least a part of the gate oxide film appeared (i.e., exposed to the surface), this time point is referred as “the time point gate oxide film appeared” hereafter, the general etching step is ceased and the surface treatment step is carried out subsequently in the same chamber.

During the general etching step a plasma gas including HBr, Cl₂ and O₂ gases is used for dry etching and a plasma gas including HBr, Ar and O₂ gases is used during the surface treatment step for dry etching. Therefore, a non-etched portion (etching residue) remained on the substrate at the time point gate oxide film appeared is etched during the surface treatment step.

In a prior dry etching step, the composition of the plasma gas is not changed even after the time point gate oxide film appeared. In addition, the concentration of HBr gas is sometimes increased for the purpose of removal of the etching residue or an over-etching to reform the gate structure. The already-appeared gate oxide film and the silicon substrate beneath the film are exposed to the plasma gas including atoms of smaller atomic weights such as hydrogen for a long time and consequently the gate oxide film and the silicon substrate are damaged seriously. In addition, the atoms, hydrogen etc., of smaller atomic weights may penetrate deep into the silicon substrate and generate defects, and then oxygen atoms are diffused in the defects resulting in “vacancy-oxygen complex defects”.

According to the exemplary embodiment of the present invention, an Ar gas of relatively large atomic weight is added to the plasma gas for etching the subject in the step after the time point gate oxide film appeared. A content of hydrogen as HBr gas can be thus reduced because the HBr gas is partially substituted by the Ar gas. Therefore, the damage of the gate oxide film and the silicon substrate can be suppressed after the time point gate oxide film appeared and subsequently the generation of the “vacancy-oxygen complex defects” can be suppressed.

To prove the above effect, the most effective treatment condition for reducing a recombination center was estimated by determining recombination lifetimes under various surface treatment conditions in the same chamber after the time point gate oxide film appeared.

A sample used was a substrate composed of a silicon substrate, a gate oxide film of 3 nm thickness and a DOPOS of 75 nm thickness. A conductive pattern was not formed on the sample.

A sequence of the determination of the lifetime was as follows.
1. Formation of a gate oxide film (4-9 nm).
2. Growth of a gate poly-silicon.
3. Dry-etching of the gate poly-silicon and plasma surface treatment.
4. DHF cleaning.
5. Side oxidation.
6. Determination of a lifetime.

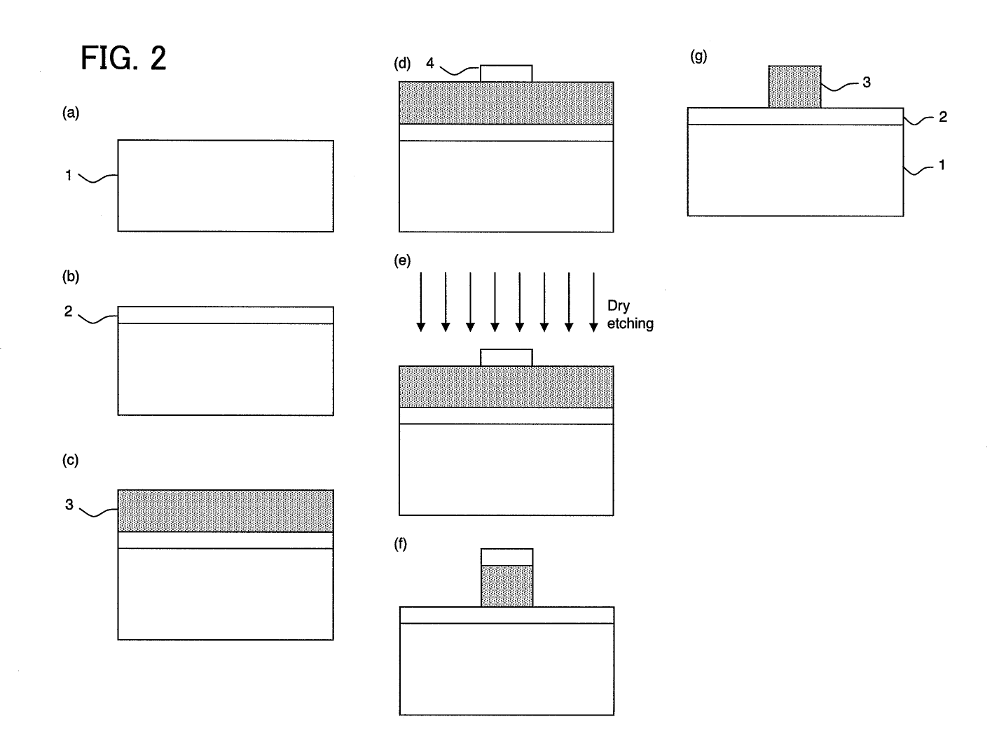

FIG. 2 shows an example of a process for fabricating a silicon substrate having a gate oxide film and a conductive layer used for the determination of the lifetime. At first a gate oxide film 2 was formed on a silicon substrate 1 as shown in (a) and (b) of FIG. 2. Next a conductive layer 3 (poly-silicon) was formed on the gate oxide film 2 ((c) of FIG. 2) and further a resist 4 was formed on the conductive layer 3 ((d) of FIG. 2). Then the conductive layer 3 was dry-etched until the gate oxide film appeared ((e) of FIG. 2). The surface of the gate oxide film was treated using a plasma gas ((f) of FIG. 2). Finally the resist 4 was removed ((g) of FIG. 2).

A plasma gas condition during a dry-etching step before the time point gate oxide film appeared was as follows.
HBr/Cl₂/O₂=150/20/7 (sccm)
10 mT, RF (upper/lower)=500W/100W (stage temperature=40 degree C.).
RF denotes Radio Frequency.

As for the surface treatment, a period of the surface treatment was fixed to 30 seconds and it was performed under variable condition levels as follows. The treatment conditions of each level is described in a sequence of gas component (sccm), pressure (mT) and RF (upper/lower) (W).
Level 1 (conventional condition, no rare gas):

HBr/O₂=200/4, 60, 350/110
Level 2 (no O₂ gas):

HBr/O₂=200/0, 60, 350/70
Level 3 (He gas added):

HBr/O₂/He=200/4/100, 60, 350/110
Level 4 (Ar gas added):

HBr/O₂/Ar=200/4/100, 60, 350/110
Level 5 (Xe gas added):

HBr/O₂/Xe=200/5/100, 50, 400/100
Level 6 (HBr gas is substituted by Cl₂ gas):

Cl₂/O₂=200/8, 50, 400/50

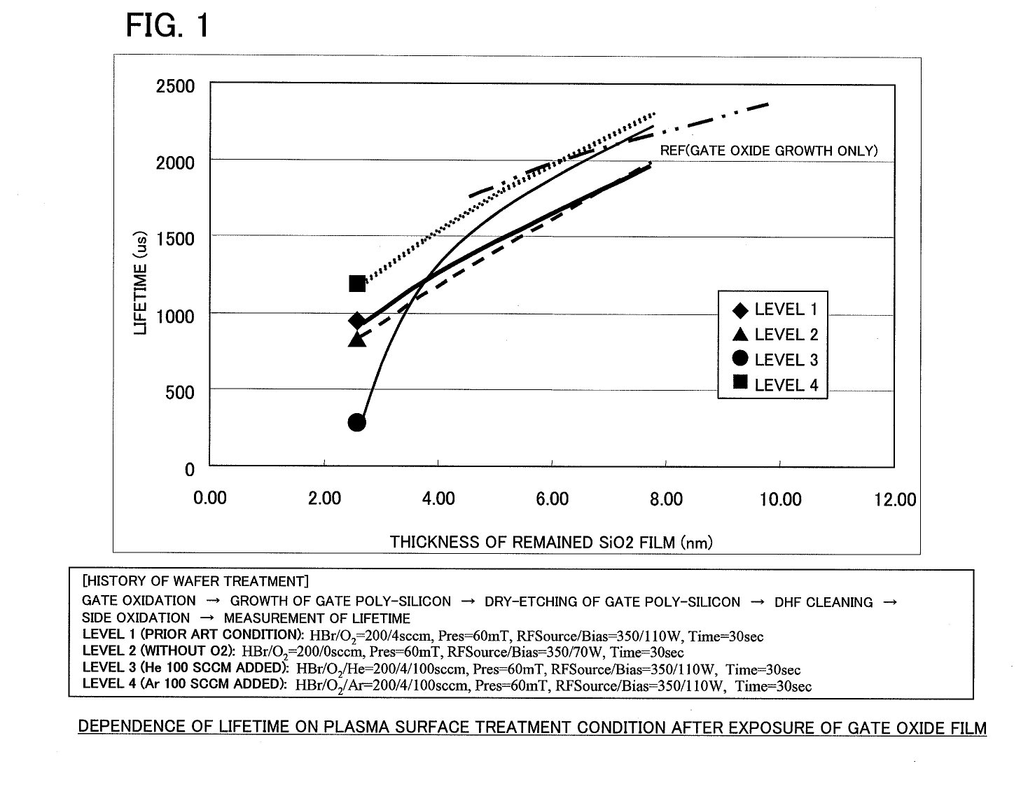

FIG. 1 shows a measured result of the lifetime of each condition level. It is presumed that the lifetime has a dependence on a thickness of the surface oxide film because the lifetime becomes long as the thickness of the surface oxide film becomes thick as shown by FIG. 1. Another considerations based on the result are as follows.
(1) The condition levels including a rare gas (levels 3 and 4) have larger lifetimes compared to the condition levels not including a rare gas (levels 1 and 2) at the same thickness of the oxide film.
(2) As for an effect of rare gas in the plasma gas, the condition including Ar gas (level 4) results the highest lifetime and next is the condition including He gas (level 3).
(3) No gate oxide film remained under the condition including Xe gas (level 5) in this experiment and there is no data in FIG. 1. However, the same or better results will be expected by optimizing the experimental condition and reducing the over-etching of the gate oxide film. The gate oxide film did not remain either by the treatment condition (level 6) in which the HBr gas is substituted by Cl₂ gas and therefore, there is no data in FIG. 1. However, considering the atomic weight of Cl atom, it is expected that a desirable surface treatment may be executed using a combination gas of Cl and rare gas having an atomic weight larger than or equal to Ar as described later.
(4) The gate oxide film could remain by the condition without O₂ (level 2) by reducing a lower RF power and the lifetime was estimated. The value of the lifetime was almost the same as that of the conventional condition with O₂ (level 1).

As a result, it is proved that the highest lifetime, that is, the least recombination center, could be obtained by the surface treatment using a plasma gas including HBr gas and Ar gas.

As for an effect of O₂ gas, it is proved that an oxygen atom in the plasma gas has almost no contribution to the “vacancy-oxygen complex defect” by comparing the results of level 1 and level 2 whose lifetimes are almost the same. Therefore, it is considered that an element in the plasma gas having an atomic weight equal to 16 or more has a very small contribution to the “vacancy-oxygen complex defect”. Thus according to the present invention atoms having an atomic weight larger than Cl (atomic weight=17) for a halogen gas and atoms having an atomic weight larger than Ar for a rare gas, for example, may be utilized in spite of embodiments above mentioned. However, it is preferable to use a plasma gas including Br and Ar, as shown in the exemplary embodiments, to obtain higher surface treatment effect.

As described above, according to the present invention, a gate structure can be formed without generating an irreparable defect (recombination center) by adding a plasma treatment for several tens of seconds using a combination gas including Br and Ar after the time point gate oxide film appeared in the same chamber that a gate etching treatment was done. Preferably the starting point of the additional surface treatment is just from the time point gate oxide film appeared; however, the starting point can be to some extent earlier or later to the time point gate oxide film appeared.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modification aforementioned.

What is claimed is:

1. A method for manufacturing a semiconductor device comprising:
forming a gate oxide film on a semiconductor substrate,
forming a conductive layer on the gate oxide film, and
dry-etching the conductive layer to form a gate, wherein the method further comprising:
treating a surface of the gate oxide film using a plasma gas including a halogen atom having an atomic weight not less than chlorine Cl and a rare gas atom having an atomic weight equal to or more than argon Ar.

2. The method as defined in claim 1, wherein said surface treating starts just after exposure of at least a part of the gate oxide film.

3. The method as defined in claim 1, wherein said surface treating starts after completion of said dry-etching.

4. The method as defined in claim 1, wherein said dry-etching is carrying out using a plasma gas comprising HBr, Cl₂ and O₂.

5. The method as defined in claim 1, wherein the halogen atom comprises bromine Br.

6. The method as defined in claim 1, wherein the rare gas atom comprises argon Ar.

7. The method as defined in claim 1, wherein said conductive layer includes at least one element of a group consisting of Si, W, Ti, Co, Al, Ta and Ni.
